(19) United States
(12) Patent Application Publication
(10) Pub. No.: US 2014/0084766 A1
(43) Pub. Date: Mar. 27, 2014

(54) Cabinet

(71) Applicants: Michael Charles Smith, Everett, WA (US); Robert Williams Nims, Everett, WA (US); Thomas Glen Rivard, Everett, WA (US)

(72) Inventors: Michael Charles Smith, Everett, WA (US); Robert Williams Nims, Everett, WA (US); Thomas Glen Rivard, Everett, WA (US)

(73) Assignee: WESTERN SYSTEMS, INC., Everett, WA (US)

(21) Appl. No.: 13/624,747

(22) Filed: Sep. 21, 2012

(51) Int. Cl. H05K 5/02

(52) U.S. Cl. CPC H05K 5/0217
USPC 312/292; 312/326

(57) ABSTRACT

The invention described herein is a traffic signal cabinet that fits the footprint of existing traffic signal cabinets, provides an easily accessible compartment that holds a BBS, and a segregated compartment for batteries.

### CROSS-REFERENCES TO RELATED APPLICATIONS

None

### STATEMENT REGARDING FEDERALLY SPONSORED RESEARCH OR DEVELOPMENT

Not Applicable

### INCORPORATION-BY-REFERENCE OF MATERIAL SUBMITTED ON A COMPACT DISC

Not Applicable

### BACKGROUND OF INVENTION

On Dec. 10, 1868, the first traffic signals (also known as traffic lights) were installed outside the British Houses of Parliament in London. Today, one can find traffic signals on any busy intersection where competing traffic flow creates potential hazards for pedestrians and vehicles. Also, at each of these intersections, generally on a sidewalk, there is at least one traffic signal cabinet which houses power, switches, circuits, etc. that controls the traffic signals.

Traffic signal cabinets built to the National Electrical Manufacturers Association (“NEMA”) standard account for the majority of traffic signal cabinets installed in North America. NEMA traffic signal cabinets sizes are most often designated by a letter of the alphabet where A would be the smallest and Z the largest. The cabinet with the best ratio of size to functionality is the NEMA P cabinet. NEMA Type P, Stretch P, Type 6, and R signal cabinets are designed to fit on a base having dimensions of approximately 44″(W)×26″(D).

As traffic increases and the technology needed to manage traffic becomes more complex, traffic signal cabinets have been required to hold more equipment within a limited amount of space. At this same time, municipalities are also looking at ways to continue traffic signal operation during power outages.

Power outages create traffic gridlock, block emergency vehicle response and impede the ability for the public to evacuate hazardous situations. Adding an uninterruptable power supply to a signalized intersection allows the intersection to remain fully functional during power outages. An uninterrupted power supply can be accomplished by adding a battery backup system. This is done by adding an electrical generator or by adding a combination of both battery backup system and generator.

Traffic signal battery backup systems are comprised of, at a minimum, an inverter, transfer switch, and valve regulated lead acid batteries. A standard battery backup system includes four 70 pound valve regulated lead acid batteries along with the inverter and switch. The total package weighs around 300 pounds and requires 6.25 cubic feet of space. The battery backup system must be incorporated within, mounted to or placed nearby the traffic signal cabinet. Ease of access to equipment for service and during power outages is a high priority.

In a prior art NEMA traffic signal cabinet having a battery backup system, the batteries, inverter and transfer switch are housed within the same traffic signal cabinet compartment. The one positive feature of this cabinet design is that it doesn't require additional real estate on the street corner. However, there are several design flaws.

Functionality of the NEMA traffic signal cabinet is limited due to the space requirements of the battery backup system. In this configuration, valve regulated lead acid batteries are forced into the same storage location as with the rest of the cabinet electronics. Additionally, the weight, size and location of the batteries in this configuration make it difficult for technicians to safely access and maintain the battery backup system. Finally, if the batteries fail, wiring and other electronics may be compromised.

In another prior art NEMA traffic signal cabinet, a second cabinet, containing the battery backup system, is mounted to the outside wall of an existing traffic signal cabinet. This design allows maximum signal cabinet functionality while isolating the batteries from the traffic signal cabinet electronics. Although battery access is good, there are several design flaws.

First, this cabinet increases the curbside space requirements (also known as footprint) of the traffic signal cabinet. Real estate available for traffic signal cabinets is limited. Each corner must have enough space for pedestrian congestion and meet the requirement of the Americans with Disabilities Act of 1990. Second, traffic signal cabinet add-ons are secured by drilling holes in both the existing traffic signal cabinet and battery backup cabinet. An additional one and a half inch hole is drilled through both cabinets to run the wiring between the cabinets. Drilling holes and mounting the secondary battery backup cabinet nullifies the NEMA rating on both cabinets, can compromise the structural integrity of the cabinets, and allow water and weather to access delicate electronic equipment.

In a third prior art traffic signal cabinet, a second standalone battery backup cabinet is added to the street corner. This variation has two major drawbacks—space and cost. Two cabinets placed on two separate concrete foundations require more real estate than any other design. As discussed in detail above, real estate on curbs is at a premium. It is substantially more expensive to add a second cabinet with a second foundation that must be connected by running underground conduit between both cabinets.

### BRIEF DESCRIPTION OF INVENTION

The invention described herein is a NEMA traffic signal cabinet with battery backup system that fits the curbside footprint of existing NEMA Type P, Type 6 and Type R traffic signal cabinets. The inverter control panel and transfer switch are in the main traffic signal compartment along with the other traffic signal components. In one compartment, technicians can access all the electronics and wiring while viewing the equipment display panels. This design incorporates new technology which allows the cabinet to meet NEMA TS 1 and NEMA

TS 2 standards having a maximum of 64 channels of detection with a 16 position load bay. An external auxiliary generator compartment has been added to the main compartment door to facilitate uninterrupted power when power outages exceed the capacity of the batteries. A second externally accessed compartment has been built into the side of the cabinet to house the valve regulated lead acid batteries.

BRIEF DESCRIPTION OF THE SEVERAL VIEWS OF THE DRAWINGS Other features and advantages of the present invention will become apparent in the following detailed descriptions of the preferred embodiment with reference to the accompanying drawings, of which:

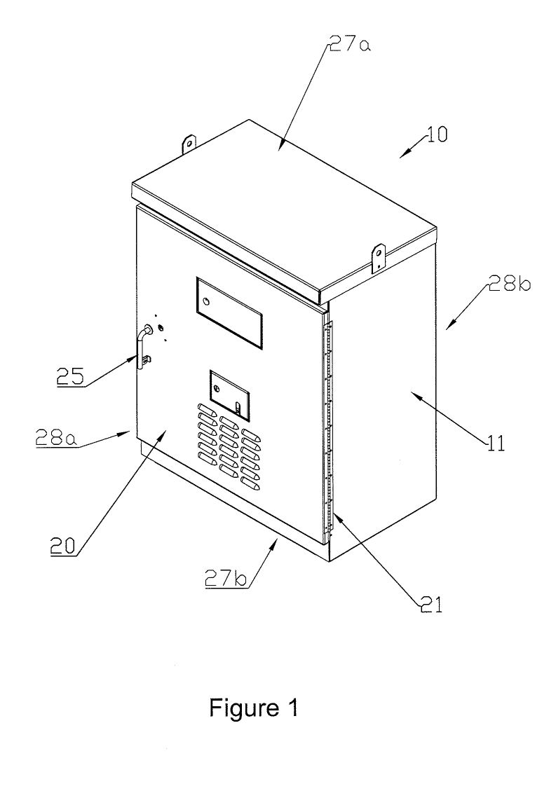

FIG. 1 is a perspective view of a first preferred embodiment the traffic signal cabinet;

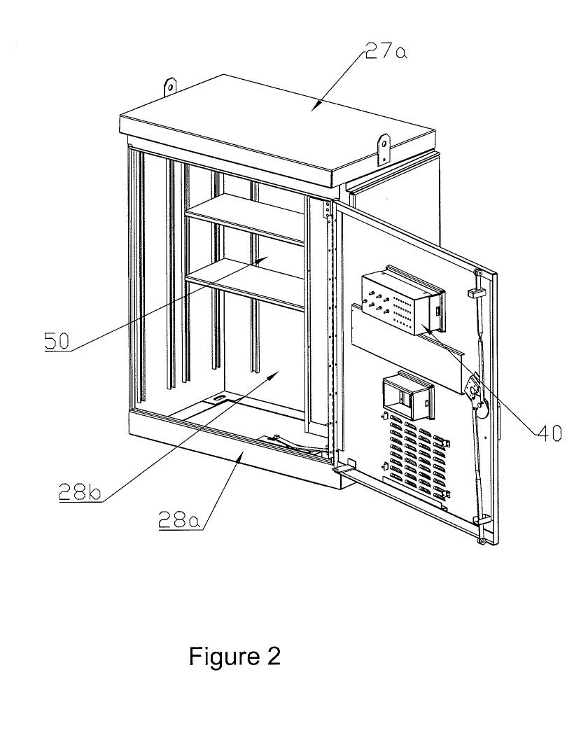

FIG. 2 is a perspective view of a first preferred embodiment of the traffic signal cabinet showing the main compartment;

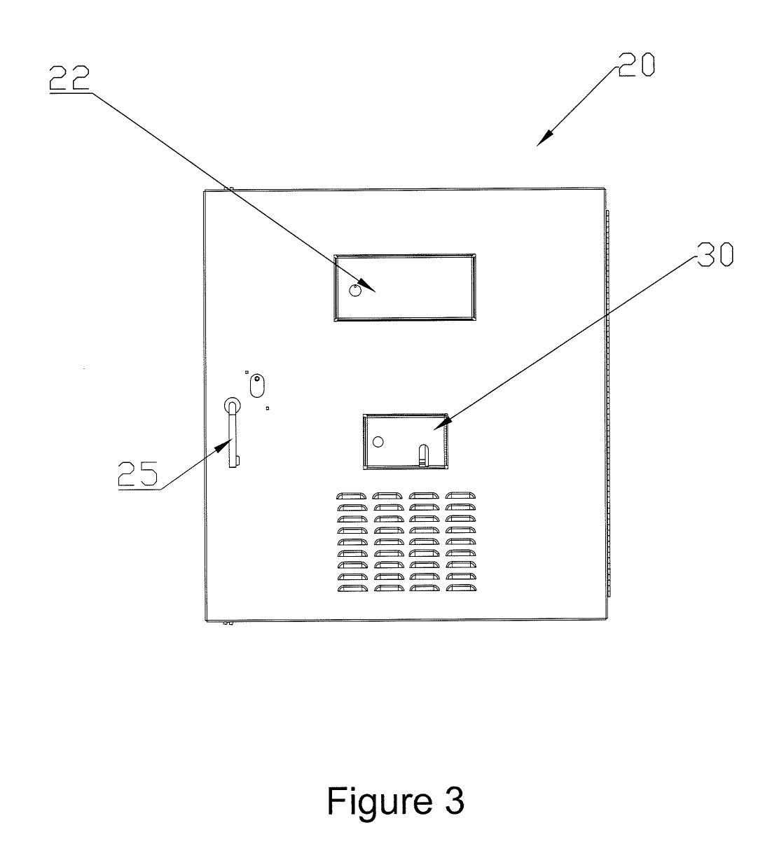

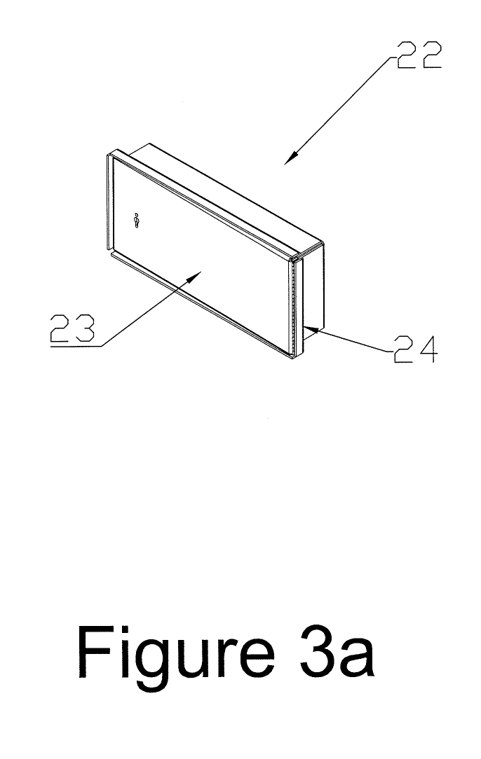

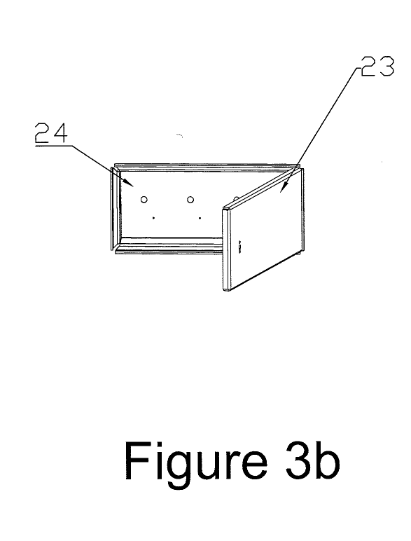

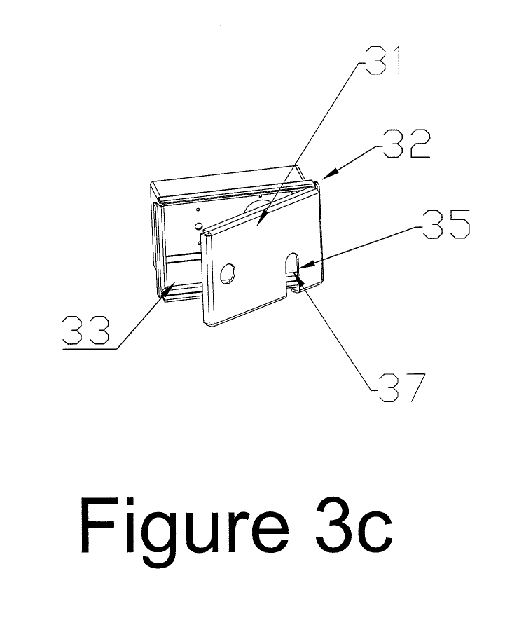

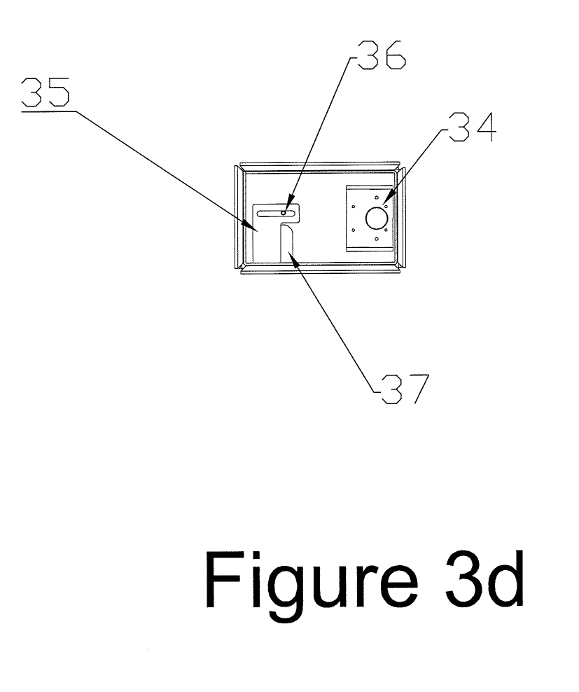

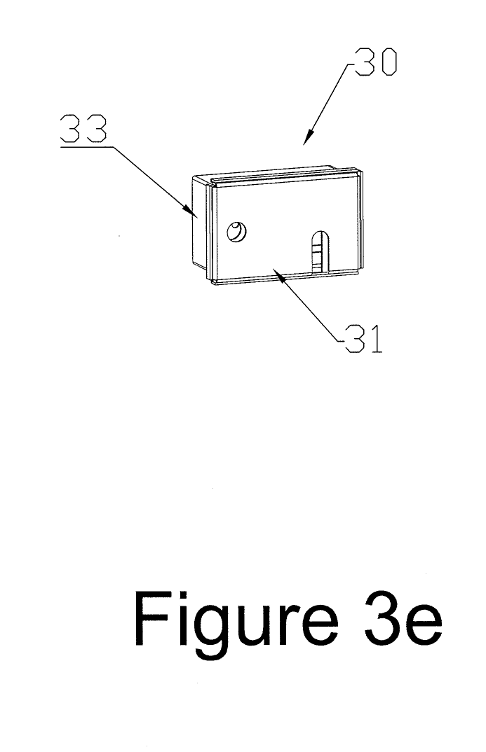

FIG. 3 is a front view of the panel door;

FIG. 3a is a perspective view of the police access panel assembly in the closed position;

FIG. 3b is a perspective view of the police access panel assembly in the open position;

FIG. 3c is a perspective view of the generator access panel assembly in the closed position;

FIG. 3d is a perspective view of the generator access panel assembly in the open position;

FIG. 3c is a top, front view of the generator panel assembly panel door;

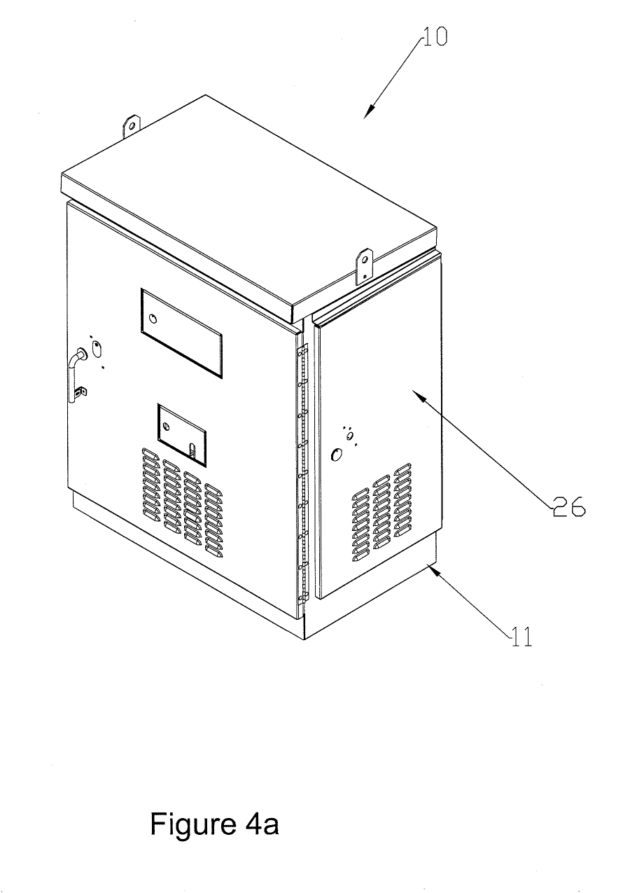

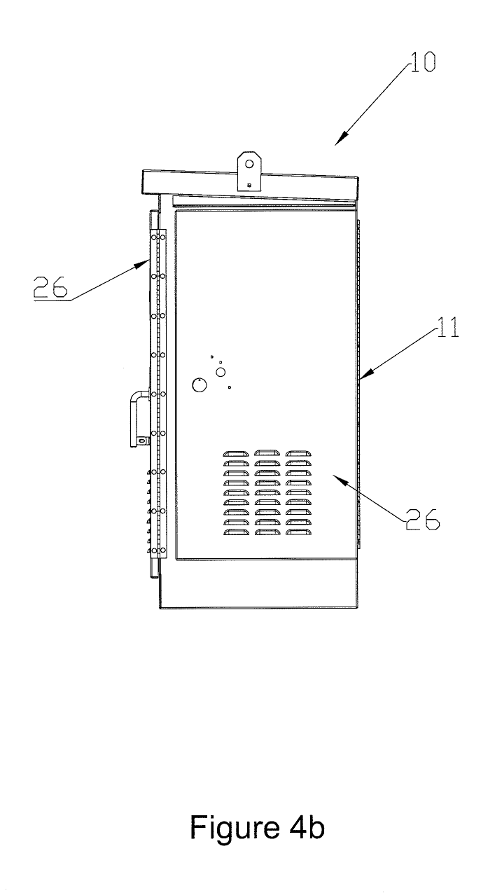

FIG. 4a is a perspective view of a second preferred embodiment of the traffic signal cabinet;

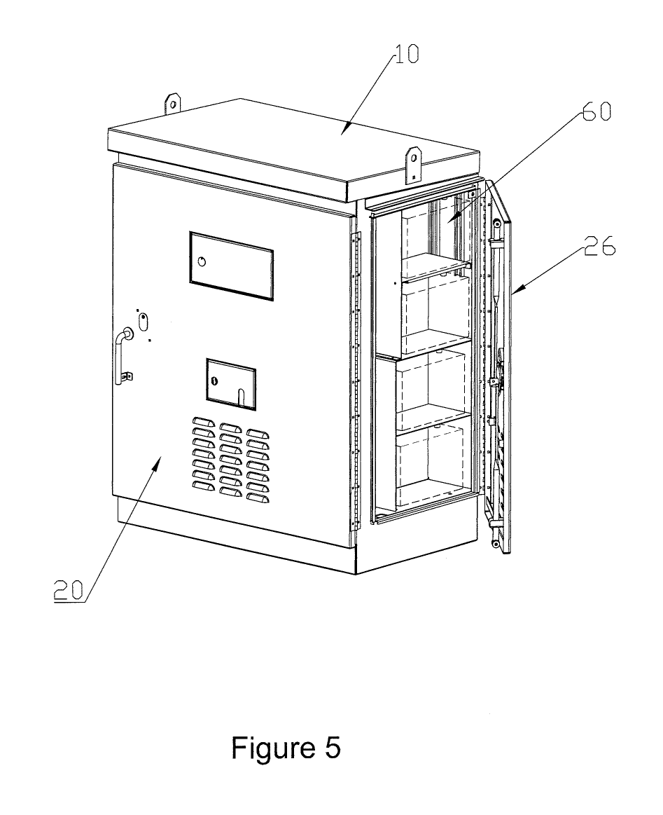

FIG. 5 is a perspective view of a second preferred embodiment of the traffic signal cabinet showing the auxiliary compartment with batteries shown in dotted lines.

### DETAILED DESCRIPTION OF THE INVENTION

The present invention is described more fully hereinafter with reference to the accompanying drawings, in which preferred embodiments of the invention are shown. This invention may, however, may be embodied in many different forms and should not be construed as limited to the embodiments set forth herein; rather, these embodiments are provided so that this disclosure will be thorough and complete and will fully convey the scope of the invention to those skilled in the art.

Referring to FIG. 1 through FIG. 3d, in a preferred embodiment, the traffic signal cabinet (10) comprises a main door (20) which is hingedly (21) attached to a cabinet (11). The cabinet comprises a main (or front) compartment (50). A battery back-up system having at least an inverter display panel, transfer switch and wiring reside in the main compartment (50). The main compartment (50) also comprises at least one terminal facility, load bay power panel, detection panel, card rack, controller, monitor, vehicle detection system. Preferably, the traffic signal cabinet (10) is wired to meet NEMA TSI, NEMA TS2 Type 1 or TS2 Type 2 standards. A person having ordinary skill in the art will note that other equipment can be housed in the main compartment (50) so long as room is available.

Preferably, the cabinet (11) is double flanged where it meets the main door (20). The main door (20) has at least one handle (25) that allows the main door (20) to be pulled open or closed shut. Preferably, the main door (20) comprises a main door stop which is a two-position, three point stop that accommodates open-angles at 90, 125, and 150 degrees. The cabinet (11) comprises a top (27a), a bottom (27b), front (28a) and a rear (28b). Preferably, the top (27a) is sloped at least 1″ toward the rear (28b) to facilitate water runoff Also, preferably, the traffic signal cabinet (10) is fabricated from 5052-H32 0.125″ thick aluminum.

The main door (20) comprises a generator access panel assembly (30) and a police access panel assembly (22). The police access panel assembly (22) comprises a police access container (24) and a police access panel door (23). The police access panel door (23) is hingedly attached to the police access container (24). The police access panel assembly is recessed into the main door (20) so that the police access panel door (23) sits flush with the main door (20). Preferably, the police access door (22) comprises a conventional police lock. The police door gives emergency personal access.

The police access container (24) comprises, at a minimum, a “Flash Switch” and a “Signals ON/OFF Switch”. The Flash Switch allows the user to place the traffic signal in normal signal operations or into emergency flash operations. The Signal ON/OFF Switch renders the field signal displays electrically dead while maintaining controller operations for purpose of monitoring controller operations.

The generator access panel assembly (30) comprises a generator container (33) and a generator access panel door (31). The generator access panel door (31) is hingedly (32) attached to the generator compartment (33). The generator access panel assembly (30) is recessed into the main door (20) so that the generator access panel door (31) sits flush with the main door (20). The generator access panel door (31) comprises a generator cable cover (35) and defines a cord access hole (37). The generator cable cover (35) is secured in place utilizing a means to secure. However, in the preferred embodiment, the generator cable cover is secured in place using a cover weld stud (36) and a nut. Preferably, the generator access panel door (31) comprises a key or combination locking system (34).

The generator container (33) comprises a means to couple a generator to the electronics contained in the traffic signal cabinet (10). More specifically, the traffic signal cabinet (10) comprises a connector which accepts an electrical plug. If the connector is not engaged with an electrical plug, then the generator cable cover (35) will cover and seal the cord access hole (37). If an electrical plug is mated with the connector, the cord from the electrical plug will extend through the cord access hole (37). The generator cable cover (35) slides to cover the portions of the cord access hole (37) not occupied by an electrical cord. The purpose of this is to prevent weather and vandals from disturbing the power from the generator to the traffic signal cabinet (10). The generator cable cover (35) is locked in place via a stud and wing nut (36).

Referring to FIG. 5, the cabinet (11) further comprises a side door (26). Preferably, the side door (26) is hingedly attached to the traffic signal cabinet (11). Preferably, the side door (26) comprises a handle to allow it to be easily opened/closed and a key or combination locking system.

The side door (26) defines a side compartment (60). The side compartment (60) allows for segregated storage of at least one battery used to power the battery back-up system.

In a preferred embodiment, the traffic signal cabinet main access door (20) further comprises a technical switch (40). Referring to FIG. 1c, the technical switch (40) is mounted to the interior portion of the traffic signal cabinet main access door (20) and is hingedly attached to the cabinet main door (20) at its bottoms side. In its closed position, the technical switch (40) allows access to switch wiring for maintenance purposes, for example. Referring to FIG. 5b, in its open position, toggles are shown for operations. Preferably, the technical switch (40) comprises, at least, access to: (1) Controller ON/OFF Switch; (2) Signals ON/OFF Switch; (3)

Stop Time Switch; (4) Technician Flash Switch; (5) Pre-Empt Test Switches. These switches perform the following functions:
Controller ON/OFF Switch: This switch renders the controller and load-switching devices electrically dead while maintaining flashing operations for purpose of changing the controller or load-switching devices.
Signals ON/OFF Switch: This switch renders the field signal displays electrically dead while maintaining controller operation for purpose of monitoring controller operations.
Stop Time Switch: This switch has 3-position switch labeled “Normal” (up), “Off” (center), and “On” (down). With the switch in the “Normal” position, a stop timing command shall be applied to the controller by the police flash switch or the MMU (Malfunction Management Unit). When the switch is in its “Off” position, stop timing commands shall be removed from the controller. The “On” position shall cause the controller to stop time.
Technician Flash Switch: This switch places the field signal displays in flashing operation while the controller continues to operate. This flash shall have no effect on the operation of the controller or MMU.
Pre-Empt Test Switches: All six preempt inputs shall have disconnect/test switches.

These switches shall have three positions labeled “On” (up) which shall connect the controller to the Opticom output, “Off” (center) which shall disconnect the controller from the Opticom output, and “Test” (down) which shall provide a momentary true input to the controller.

In a preferred embodiment, the traffic signal cabinet (10) will have the nominal dimensions of 44″ (W)×26″ (D) which meets the footprint dimensions of existing cabinets and is specified in Section 7.3 of NEMA Standards for Type P or Type 6 cabinets. The traffic signal cabinet's (10) base has continuously welded interior mounting reinforcement plates with the same anchor bolt hole pattern as the footprint dimensions.

I claim as my invention:

1. A traffic signal cabinet comprising a cabinet and a main door:
where the main door is connected to the cabinet;
where the cabinet defines a main compartment;
where the cabinet further comprises a battery backup equipment.

2. The traffic signal cabinet of claim 1 where the traffic signal cabinet further comprises a second door:
where the second door is connected to the cabinet;
where the cabinet further defines a second compartment;
where the second compartment is segregated from the main compartment;
where the second compartment comprises at least one battery.

3. The traffic signal cabinet of claim 1 where main door comprises a generator access panel assembly:
where the generator access panel assembly comprises a generator access panel door and a generator compartment;
where the generator access panel door is hingedly attached to the generator compartment;
where the generator access panel assembly is recessed into the panel door;
a means to lock the generator access door.

4. The traffic signal cabinet of claim 3 where the main door comprises a police access panel assembly:
where the police access container comprises a police access container and police access panel door;
where the police access container assembly is recessed into the panel door.

5. The traffic signal cabinet of claim 4 where the main door comprises a generator access panel assembly and a police access panel assembly.

6. The traffic signal cabinet of claim 5 where the main door further comprises an technical switch; where the technical switch is mounted on the interior portion of the main door.

7. The traffic signal cabinet of claim 6 has nominal dimensions of 44″ (W)×36″ (D).
